(19) United States
(12) Patent Application Publication
(10) Pub. No.: US 2014/0145221 A1
(43) Pub. Date: May 29, 2014

(54) LED LAMP STRUCTURE WITH HEAT SINK

(71) Applicant: HELIO OPTOELECTRONICS CORPORATION, Zhudong Town (TW)

(72) Inventors: Ming-Hung Chen, Zhudong Town (TW); Kun-Yang Hsieh, Zhudong Town (TW); Shin-Chieh Lin, Zhudong Town (TW)

(73) Assignee: Helio Optoelectronics Corporation, Zhudong Town (TW)

(21) Appl. No.: 13/737,616

(22) Filed: Jan. 9, 2013

(30) Foreign Application Priority Data
Nov. 23, 2012 (TW) 101222803

(51) Int. Cl. H01L 33/64; H01L 33/60

(52) U.S. Cl. CPC H01L 33/64; H01L 33/60
USPC 257/89; 257/88

(57) ABSTRACT

An LED lamp structure with a heat sink includes a reflection cup, an LED module, and a cover, in addition to the heat sink. The reflection cup has an inside bottom surface, a reflection surface, an outside bottom surface, and a light exit. The LED module is thermally conductively and fixedly provided on the inside bottom surface. The cover covers the LED module. The heat sink is thermally conductively connected to the outside bottom surface. The LED lamp structure is efficient in not only light extraction but also heat dissipation.

### BACKGROUND OF THE INVENTION

1. Technical Field

The present invention relates to a light-emitting diode lamp structure and, more particularly, to a light-emitting diode lamp structure with a heat sink.

2. Description of Related Art

Thanks to the increase in brightness and the continuous improvement of light extraction efficiency, light-emitting diodes (LEDs) have in recent years been massively used in lighting-related applications. In fact, most of the traditional light bulbs or cold-cathode tubes required in the backlights of handheld devices, the backlights of liquid crystal displays of various sizes, the light sources of projectors, and so on have been replaced by LEDs. In addition, the advancements in color temperature control, frequency stabilization, and light color mixing efficiency have made it possible to use LEDs extensively in everyday lighting.

Now that LEDs are in wide use, it is highly desirable to further increase their light extraction efficiency by effective light beam concentration and to improve heat dissipation from LEDs, with a view to saving more energy and expanding the applications of LEDs.

In today's LED lighting technology, the design of reflection cups (e.g., reflective lamp cups or lampshades) is a major subject of innovation. However, most lampshade design efforts are directed toward esthetic novelty and based on commercial considerations, with little attention paid to the planning of light refraction. As a large portion of the light emitted by an LED light source scatters without being reflected or concentrated by its lampshade, which leads to inefficient use of energy, it is imperative for lampshade or lamp designers to develop a highly efficient lampshade which can direct more light to the light exit of an LED lamp, and effectively concentrate the portion of light that is otherwise not reflected or concentrated by the lampshade, and thereby increase the overall light extraction efficiency of the LED light source. It is also important to provide more efficient heat dissipation so that the service life of an LED light source can be extended.

### BRIEF SUMMARY OF THE INVENTION

It is an object of the present invention to provide an LED lamp structure having a heat sink, wherein the LED lamp structure includes a reflection cup, an LED module, and a cover, in addition to the heat sink, and wherein the LED lamp structure is efficient not only in light extraction but also in heat dissipation.

To achieve the above object, the present invention provides an LED lamp structure having a heat sink, wherein the LED lamp structure includes: a reflection cup having an inside bottom surface, a reflection surface, an outside bottom surface, and a light exit; an LED module thermally conductively and fixedly provided on the inside bottom surface; a cover covering the LED module; and the heat sink, which is thermally conductively connected to the outside bottom surface.

Implementation of the present invention at least provides the following advantageous effects:

1. The provision of the reflection cup, which is formed of a highly reflective material or coated with a highly reflective plated film, increases light output and consequently lighting efficiency.

2. The provision of the heat sink enhances heat dissipation efficiency and thereby helps extend the service life of the LED lamp structure.

The features and advantages of present invention are described in detail hereunder to enable persons skilled in the art to understand and implement the disclosure of the present invention and readily apprehend objectives and advantages of the present invention with references made to the disclosure contained in the specification, the claims, and accompanying drawings.

### BRIEF DESCRIPTION OF THE SEVERAL VIEWS OF THE DRAWINGS.

FIG. 1 is a sectional view of an LED lamp structure with a heat sink according to an embodiment of the present invention.

FIG. 2A is a perspective view of a reflection cup according to the embodiment shown in FIG. 1.

FIG. 2B is a sectional view of the reflection cup shown in FIG. 2A.

FIG. 3 is a sectional view of an LED lamp structure with a heat sink according to another embodiment of the present invention.

FIG. 4 shows how LED chips are arranged in an LED module according to an embodiment of the present invention.

FIG. 5A is a sectional view of a cover according to an embodiment of the present invention.

FIG. 5B is a sectional view of a cover according to another embodiment of the present invention.

FIG. 6 is a sectional view of an LED lamp structure with a heat sink according to still another embodiment of the present invention.

FIG. 7 is a sectional view of an LED lamp structure with a heat sink according to yet another embodiment of the present invention.

### DETAILED DESCRIPTION OF THE INVENTION

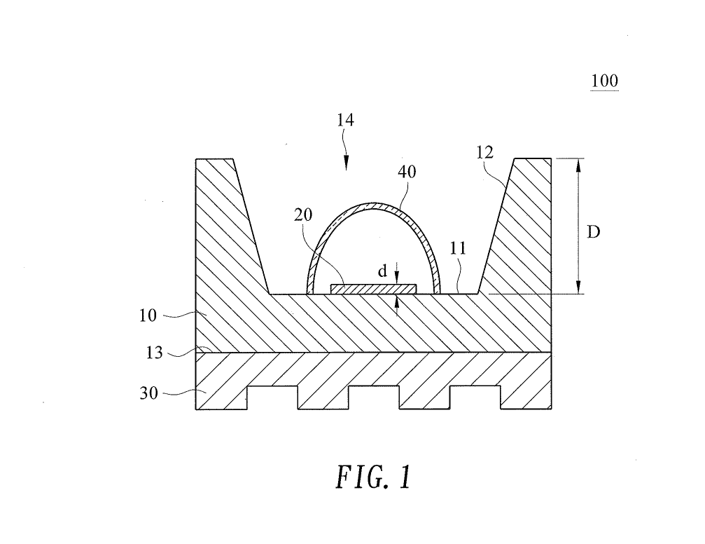

Referring to FIG. 1 for an embodiment of the present invention, an LED lamp structure 100 with a heat sink 30 includes a reflection cup 10, a LED module 20, and a cover 40, in addition to the heat sink 30. The reflection cup 10 has an inside bottom surface 11, a reflection surface 12, an outside bottom surface 13, and a light exit 14. The LED module 20 is thermally conductively and fixedly provided on the inside bottom surface 11. The cover 40 covers the LED module 20. The heat sink 30 is thermally conductively connected to the outside bottom surface 13. The reflection up 10 is configured to reflect the light emitted by the LED nodule 20 and thereby project the light outward through the light exit 14. The heat sink 30 is configured to dissipate the heat generated by the LED module 20 to ambient air. In order for the reflection cup 10 to provide the intended reflection, the inner depth of the reflection cup 10, i.e., the distance D from the inside bottom surface 11 to the light exit 14, must be greater than the thickness d of the LED module 20.

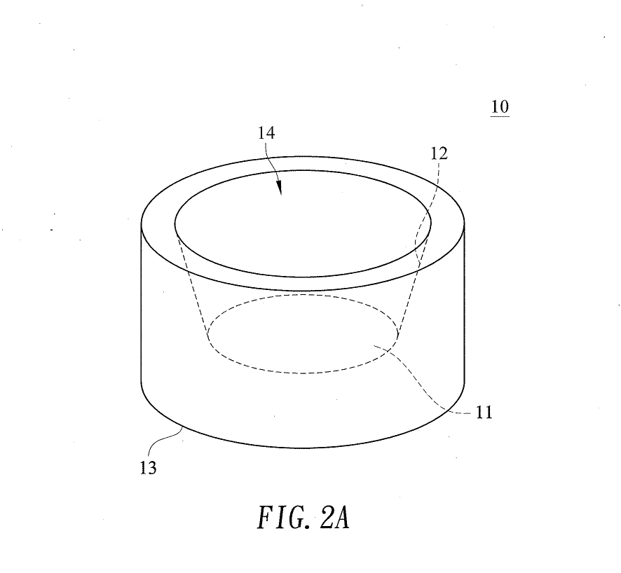

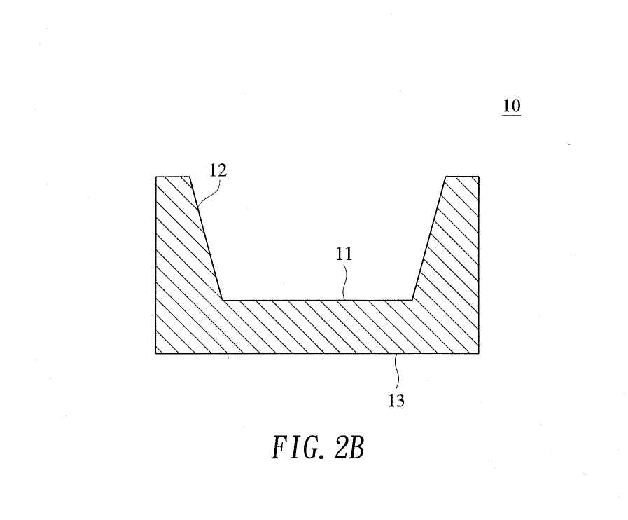

As shown in FIG. 2A and FIG. 2B, the inside bottom surface 11 and the reflection surface 12 are designed to reflect the light emitted by the LED module 20 and thereby project the light outward through the light exit 14. The reflection cup 10 may be formed of a material whose reflectivity is equal to or greater than 80%, so as to be highly reflective to incident light, i.e., capable of reflecting the light incident on the reflection surface 12 and thereby projecting the light outward through the light exit 14. The use of such a material increases the overall light extraction efficiency of the LED lamp structure 100.

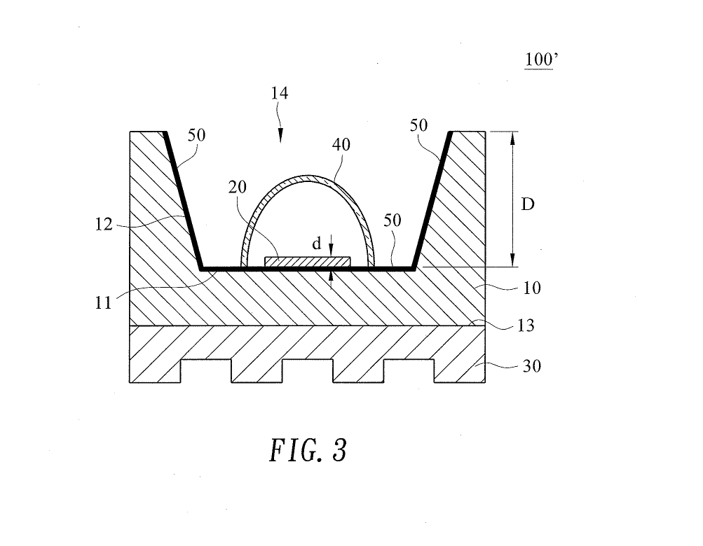

FIG. 3 shows an LED lamp structure 100′with a heat sink 30 according to another embodiment of the present invention. In the embodiment shown in FIG. 3, the reflection cup 10 is formed of a material whose reflectivity is less than 80%, and because of that, a plated film 50 is coated on the inside bottom surface 11 and the reflection surface 12 of the reflection cup 10, wherein the plated film 50 is formed of a material whose reflectivity is greater than 80%. The plated film 50 serves to reflect incident light outward through the light exit 14, thereby enhancing the overall light extraction efficiency of the LED lamp structure 100′.

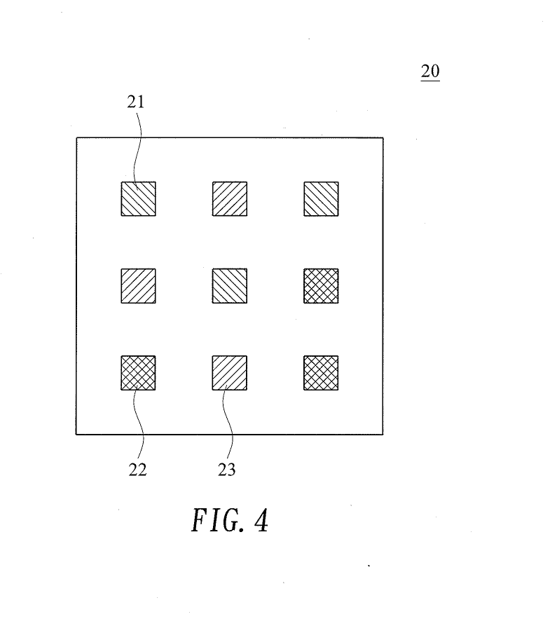

FIG. 4 shows an LED module 20 according to an embodiment of the present invention. The LED module 20 is thermally conductively and fixedly provided on the inside bottom surface 11 and is composed of at least one single-color LED, or a plurality of LEDs of different colors, or at least one chip-on-board (COB) LED chip. The LED module 20 in the embodiment shown in FIG. 4 has an array of nine COB LED chips, namely three LED chips 21, three LED chips 22, and three LED chips 23, wherein each trio is of a different color. When the LED chips in the LED module 20 are of the three colors R, G, and B, the LED module 20 can emit white light.

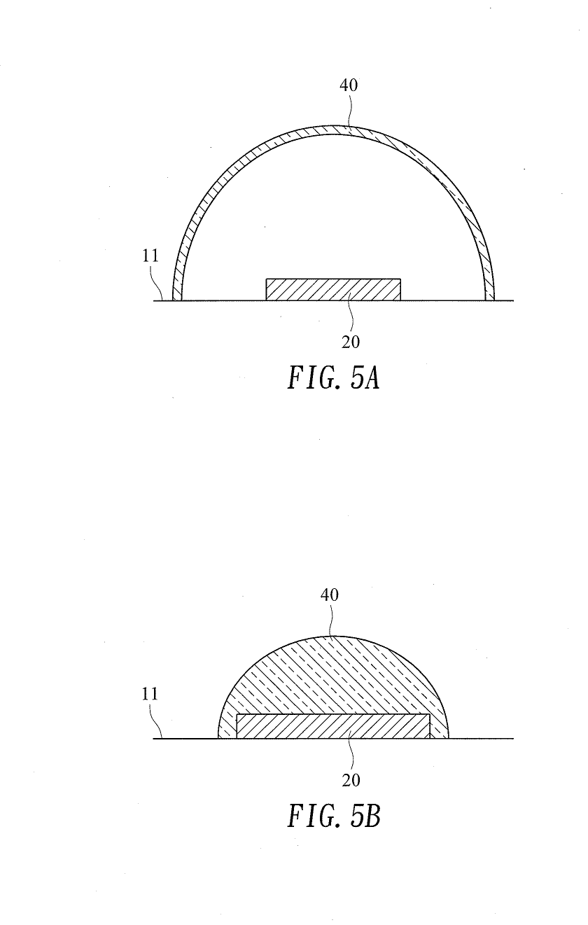

As shown in FIG. 5A and FIG. 5B, the cover 40 covers the LED module 20 on the inside bottom surface 11. The cover 40 may be a hollow cover as shown in FIG. 5A, in which case the cover 40 is not in contact with the LED module 20 and is therefore subject to relatively less of the heat generated by the LED module 20, which is advantageous. The cover 40 may alternatively be a solid cover as shown in FIG. 5B, in which case the cover 40 is in direct contact with the LED module 20.

Referring back to the LED lamp structures 100 and 100′ shown in FIG. 1 and FIG. 3, the heat sink 30 is thermally conductively connected to the outside bottom surface 13. In addition, the heat sink 30 is formed of a material capable of efficient heat dissipation and is configured to dissipate the heat generated by the entire LED lamp structure 100 or 100′ to ambient air.

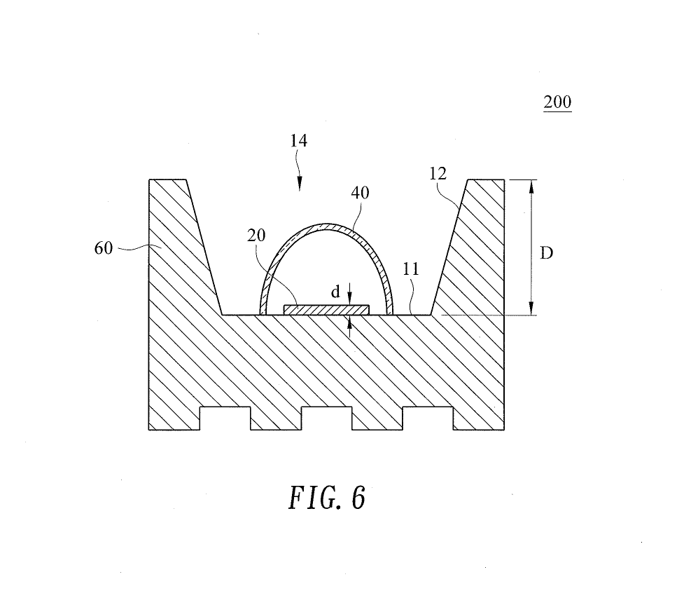

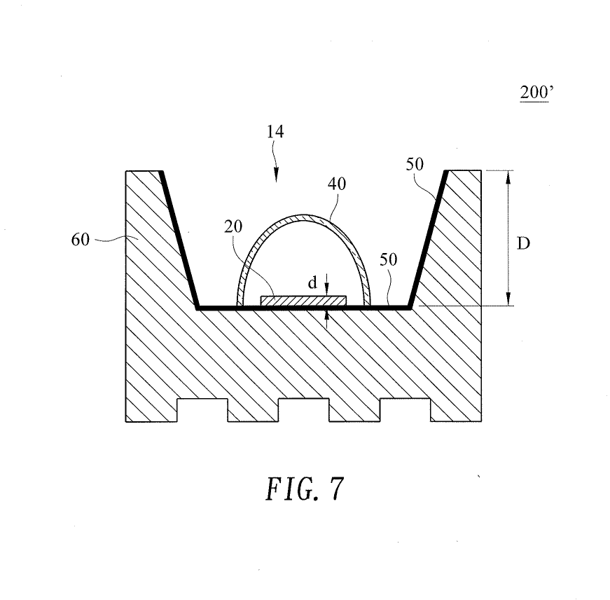

FIG. 6 and FIG. 7 show two more embodiments of the present invention, i.e., the LED lamp structure 200 and the LED lamp structure 200′. An integrally formed structure 60 is formed of a material capable of efficient heat dissipation and includes the reflection cup 10 and the heat sink 30 of the LED lamp structure 100 or 100′ in FIG. 1 or FIG. 3. The inner depth of the integrally formed structure 60, i.e., the distance D from the inside bottom surface 11 to the light exit 14 must be greater than the thickness d of the LED module 20, so as for the integrally formed structure 60 to provide the intended reflection.

In the LED lamp structure 200 shown in FIG. 6, the integrally formed structure 60 is formed of a material whose reflectivity is not less than 80%. With such a high reflectivity, the integrally formed structure 60 can reflect the light shone onto the reflection surface 12 from the LED module 20 and thereby project the light outward through the light exit 14.

In the LED lamp structure 200′ shown in FIG. 7, the integrally formed structure 60 is formed of a material whose reflectivity is less than 80%, and a plated film 50 is coated on the inside bottom surface 11 and the reflection surface 12, wherein the plated film 50 is formed of a material having a reflectivity greater than 80%. Thus, the light emitted from the LED module 20 to the plated film 50 can be reflected outward through the light exit 14.

In the LED lamp structures 200 and 200′ shown in FIG. 6 and FIG. 7, the LED module 20 is also composed of at least one single-color LED or a plurality of LEDs of different colors, and the cover 40 is a hollow cover free of contact with the LED module 20 (as shown in FIG. 5A) or a solid cover in direct contact with the LED module 20 (as shown in FIG. 5B).

In the foregoing LED lamp structures 100, 100′, 200, and 200′, the combination of the cover 40, or more particularly the phosphor powder contained therein, and the LED module 20 is intended mainly to produce the desired color and tone of light for a specific application. Most industrial and everyday applications require the emission of white light.

In order to omit white light, any of the following combinations of the cover 40 and the LED module 20 may be used: the cover 40 containing yellow phosphor powder while the LED module 20 is a blue LED chip; the cover 40 containing yellow phosphor powder mixed with red phosphor powder while the LED module 20 is a blue LED chip; the cover 40 containing yellow phosphor powder mixed with both red phosphor powder and green phosphor powder while the LED module 20 is a blue LED chip; the cover 40 containing yellow phosphor powder while the LED module 20 includes a blue LED chip and a red LED chip the cover 40 containing yellow phosphor powder mixed with red phosphor powder while the LED module 20 includes a blue LED chip and a red LED chip; the cover 40 containing yellow phosphor powder mixed with both red phosphor powder and green phosphor powder while the LED module 20 includes a blue LED chip and a red LED chip; the cover 40 being a transparent cover while the LED module 20 includes a blue LED chip, a red LED chip, and a green LED chip; and the cover 40 containing yellow phosphor powder while the LED module 20 is an ultraviolet LED chip.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and variations made to the foregoing embodiments without departing from the spirit and principles in the disclosure of the present invention should fall within the scope of the invention as set forth in the appended claims.

1. A light-emitting diode (LED) lamp structure with a heat sink, comprising:
a reflection cup having an inside bottom surface, a reflection surface, an outside bottom surface, and a light exit;
a LED module thermally conductively and fixedly provided on the inside bottom surface;
a cover covering the LED module; and
a heat sink thermally conductively connected to the outside bottom surface.

2. The LED lamp structure of claim 1, wherein the reflection cup is formed of a material having a reflectivity not less than 80%.

3. The LED lamp structure of claim 1, wherein the reflection cup is formed of a material having a reflectivity less than 80%, and the inside bottom surface and the reflection surface are coated with a plated film.

4. The LED lamp structure of claim 3, wherein the plated film is formed of a material having a reflectivity greater than 80%.

5. The LED lamp structure of claim 1, wherein the LED module is composed of at least one single-color LED.

6. The LED lamp structure of claim 1, wherein the LED module is composed of a plurality of LEDs of different colors.

7. The LED lamp structure of claim 1, wherein the LED module is composed of at least one chip-on-board (COB) LED chip.

8. The LED lamp structure of claim 1, wherein the cover is a hollow cover and is not in contact with the LED module.

9. The LED lamp structure of claim 1, wherein the cover is a solid cover and is in direct contact with the LED module.

10. The LED lamp structure of claim 1, wherein the cover contains yellow phosphor powder, and the LED module is a blue LED chip or an ultraviolet LED chip or is composed of a blue LED chip and a red LED chip.

11. The LED lamp structure of claim 1, wherein the cover contains yellow phosphor powder mixed with red phosphor powder, and the LED module is a blue LED chip or is composed of a blue LED chip and a red LED chip.

12. The LED lamp structure of claim 1, wherein the cover contains yellow phosphor powder mixed with both red phosphor powder and green phosphor powder, and the LED module is a blue LED chip or is composed of a blue LED chip and a red LED chip.

13. The LED lamp structure of claim 1, wherein the cover is a transparent cover, and the LED module includes a blue LED chip, a red LED chip, and a green LED chip.

14. The LED lamp structure of claim 1, wherein the reflection cup and the heat sink are an integrally formed structure of a material capable of efficient heat dissipation.
